(19) United States
(12) Patent Application Publication
(10) Pub. No.: US 2003/0141563 A1
(43) Pub. Date: Jul. 31, 2003

(54) Light emitting diode package with fluorescent cover

(76) Inventor: Bily Wang, Hsin-Chu (TW)

Correspondence Address: Hung Chang LIN, 8 Schindler Court, Silver Spring, MD, 20903, US

(21) Appl. No.: 10/056,339

(22) Filed: Jan. 28, 2002

(51) Int. Cl. H01L 33/00

(52) U.S. Cl. 257/432; 257/98; 257/704

(57) ABSTRACT

A blue LED or ultra-violet (UV) LED chip is packaged with a cover of fluorescent material. When the LED emits blue or UV light, the light is converted into colorless or white light radiating from the package. The package is furnished with bottom contacts for surface mounting.

### BACKGROUND OF THE INVENTION

(1) Field of the Invention

This invention relates to light emitting diodes (LED), particularly to the LED package.

(2) Brief Description of Related Art

In the prior art, colorless or white light can be produced by using a blue LED chip or a ultra-violet LED chip emitting through a fluorescent material. A typical prior structure package is shown in FIG. 1. A LED chip 10 is mounted on a metallic plate 11. The top electrode of the chip 10 is wire-bonded by wire 13 to a second metal plate serving as a lead 12 for surface mounting. The bottom electrode of the LED chip 10 is in contact with the metal plate 11, which serves as another lead for surface mounting. The chip 10 is covered with a fluorescent glue 16 as shown in FIG. 2. The glue penetrates through two via holes 14 in the metal plates 11 and 12 to strengthen the adhesion of the glue 16 to the metal plates 11 and 12 and to fix their relative positions. When the blue or UV light is emitted from the LED, the light from the package appears as colorless.

The prior art shown in FIGS. 1 and 2 consumes a great deal of fluorescent glue material and hence expense for packaging the LED. The thick glue also attenuates the light emitted from the LED.

### SUMMARY OF THE INVENTION

An object of this invention is to reduce the cost of producing colorless light. Another object of this invention is to reduce the amount of fluorescent glue used for a blue light emitting diode to produce a colorless light. Still another object of this invention is to reduce the attenuation of the light emitted from the LED due to the glue.

These objects are achieved by using a thin cover with fluorescent material.

### BRIEF DESCIPRTION OF THE SEVERAL VIEWS OF THE DRAWINGS

FIG. 1 shows the top view of a prior art LED package.

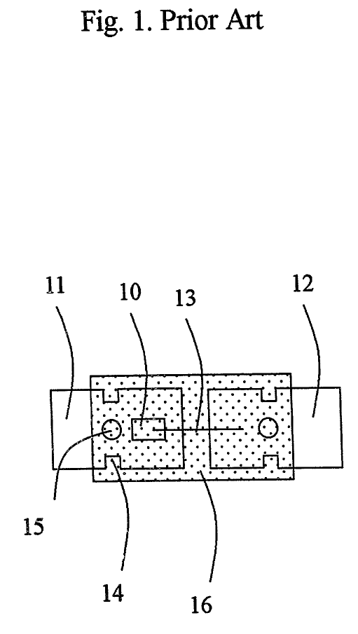

FIG. 2 shows the side view of FIG. 1.

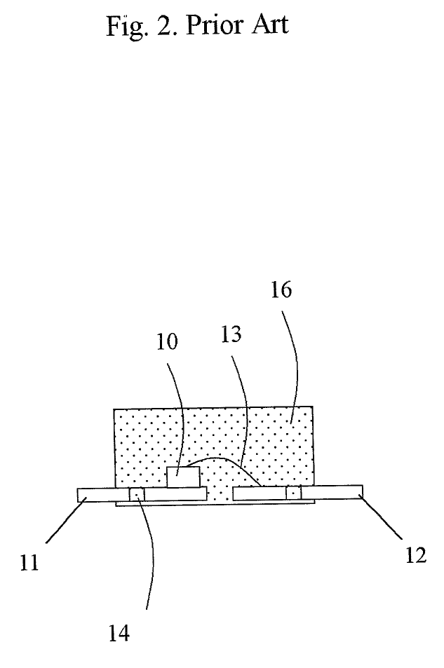

FIG. 3 shows the first embodiment of the present invention with a wrap-around fluorescent cover.

FIG. 4 shows the second embodiment of the present invention with flat fluorescent cover.

FIG. 5 shows a third embodiment of the present invention with air space between the LED and the fluorescent cover.

FIG. 6 shows a fourth embodiment of the present invention with zigzag leads.

FIG. 7 shows a fifth embodiment of the present invention with folded leads.

FIG. 8 shows a sixth embodiment of the present invention with air space between the LED and the fluorescent cover.

FIG. 9 shows a seventh embodiment of the present invention with an opaque side-wall.

FIG. 10 shows an eighth embodiment of the present invention with glue covering the total length of the leads.

FIG. 11 shows a ninth embodiment of the present invention with air space between the LED and the fluorescent cover extending to cover the length of the bottom leads.

FIG. 12 shows the tenth embodiment of the present invention similar to FIG. 11 but with zigzag leads.

FIG. 13 shows an eleventh embodiment of the present invention similar to FIG. 7 with the width of the fluorescent cover extending to cover the length of the metal leads.

FIG. 14 shows a twelfth embodiment of the present invention similar to FIG. 8 but with the width of the fluorescent cover covering the length of the metal leads.

FIG. 15 shows the thirteenth embodiment of the present invention similar to FIG. 9 but with the width of the fluorescent covering the length of the metal leads.

### DETAILED DESCRIPTION OF THE INVENTION

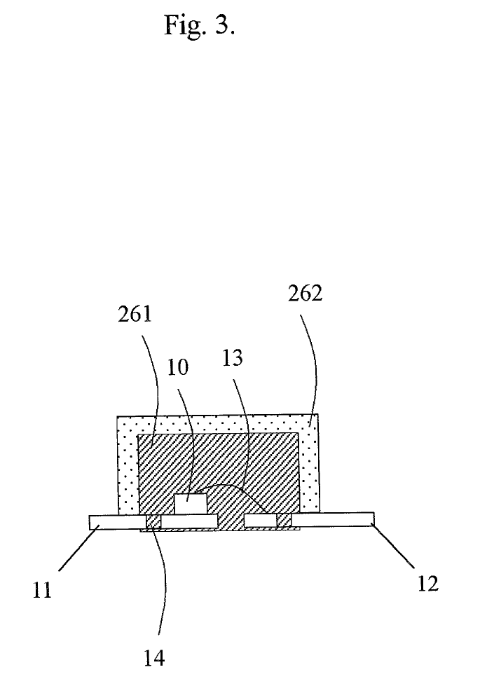

FIG. 3 shows the first embodiment of the present invention. A blue or ultra-violet LED 10 chip is mounted on a metal plate 11 serving as the contact lead for the bottom electrode of the LED 10 of a surface mount package. The top electrode of the LED 10 is wire-bonded by wire 13 to a second metal plate 12 serving as the second contact lead of the LED 10 for the surface mount package. The LED is imbedded in glue 261 which feeds through two via holes or edge recess 14 for holding the structure in place and which spreads along the bottoms of the leads 11 and 12 to fix the relative positions of the leads 11 and 12. A cover 262 composed of fluorescent material is used to cover the glue 261. When a light is emitted from the blue LED chip, the fluorescent cover converts the blue light into colorless light.

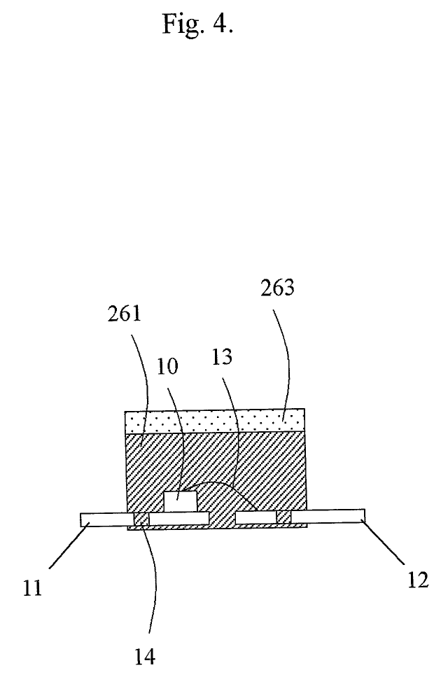

FIG. 4 shows a second embodiment of the present invention. The structure is similar to FIG. 3 except a flat fluorescent plate 263 is used to serve as the cover instead of the wrap-over cover 262 in FIG. 3. Other corresponding parts serve the same function as that in FIG. 3.

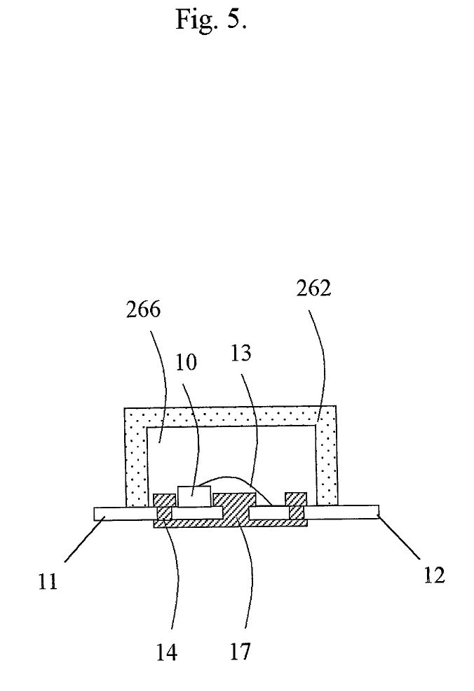

FIG. 5 shows a third embodiment of the present invention. Instead of the glue 261 used in FIG. 3, the space between the chip 10 and the fluorescent cover is back-filled with air 266. Glue 17 is used only to fill the through holes 14 in metal plates 11 and 12 and to spread along the bottom surfaces of the metal plates to hold the structure in place. The absence of glue between the chip 10 and the cover 262 reduce the attenuation of the emitted light from the LED 10.

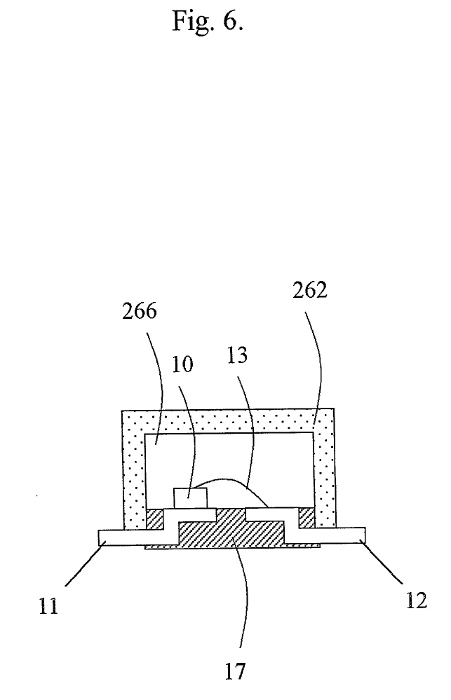

FIG. 6 shows a fourth embodiment of the present invention. The structure is similar to that in FIG. 5 except that the metal leads 11 and 12 have a zigzag shape. The zigzag leads increases the adhesion area between the glue 17 and the leads 11, 12, thereby increasing the rigidity.

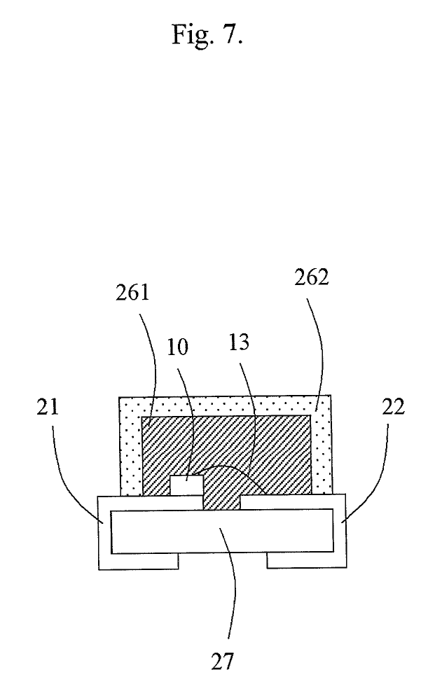

FIG. 7 shows a fifth embodiment of the present invention. The structure is similar to that in FIG. 3 except that the leads 11, 12 in FIG. 3 are replaced with folded leads 21, 22 around an insulating substrate 27. The folded leads form flat bottom contacts more suitable for surface mounting.

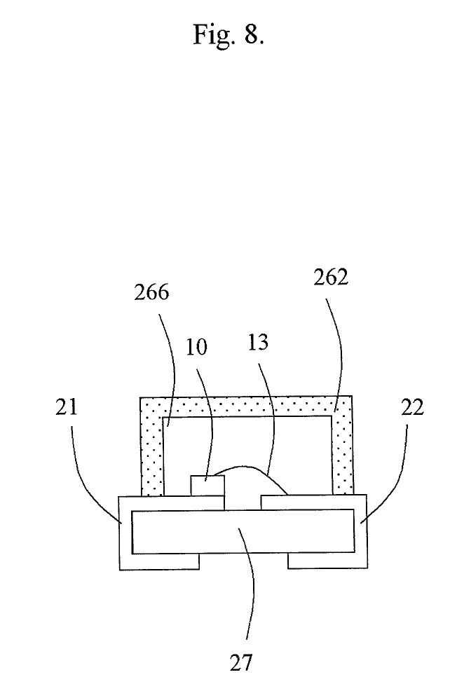

FIG. 8 shows a sixth embodiment of the present invention. The structure is similar to that in FIG. 7 except that the space 266 between the LED 10 and the fluorescent cover 262 is filled with air, which has less attenuation to the light emitted from the LED 10.

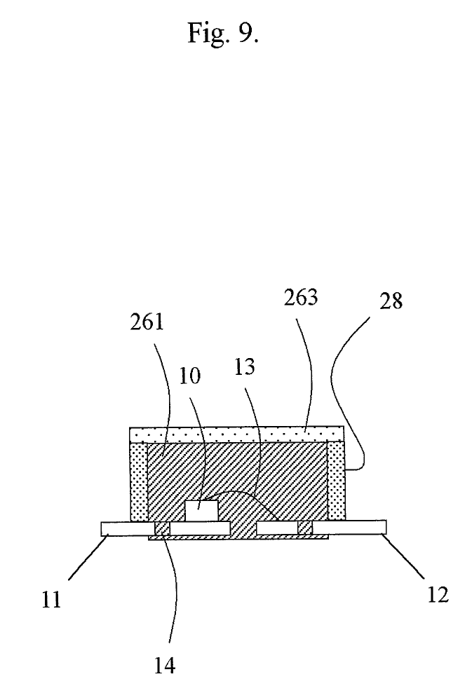

FIG. 9 shows a seventh embodiment of the present invention. The structure is similar to that in FIG. 4 except that an opaque side-wall 28 is erected around the glue 261. The opaque side-wall 28 prevents the emitted light from the LED 10 to irradiate sidewise, thereby concentrating the light toward the fluorescent cover 263.

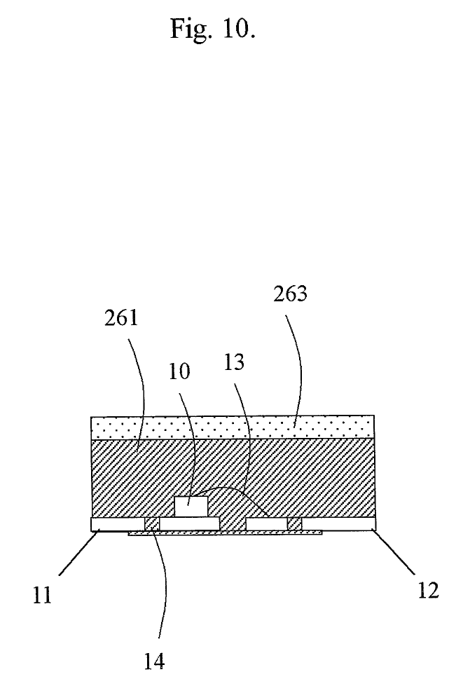

FIG. 10 shows an eighth embodiment of the present invention. The structure is similar to that in FIG. 4 except that the width of the glue 261 and the fluorescent cover 263 is extended to be of the same length as the leads 11 and 12. The glue 261 makes the leads 11 and 12 more rigid for easy surface mounting to a circuit board.

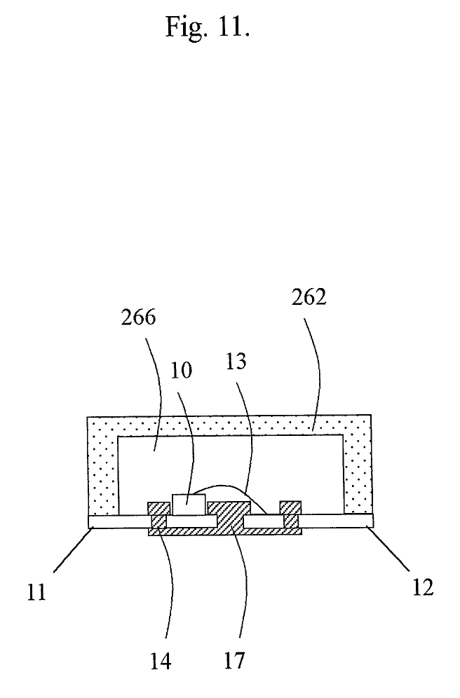

FIG. 11 shows a ninth embodiment of the present invention. The structure is similar to that in FIG. 5 except that the width of the fluorescent cover 262 is extended to be of the same length as the leads 11 and 12. The fluorescent cover 262 adds to the rigidity of the leads 11 and 12 for easy surface mounting to a circuit board.

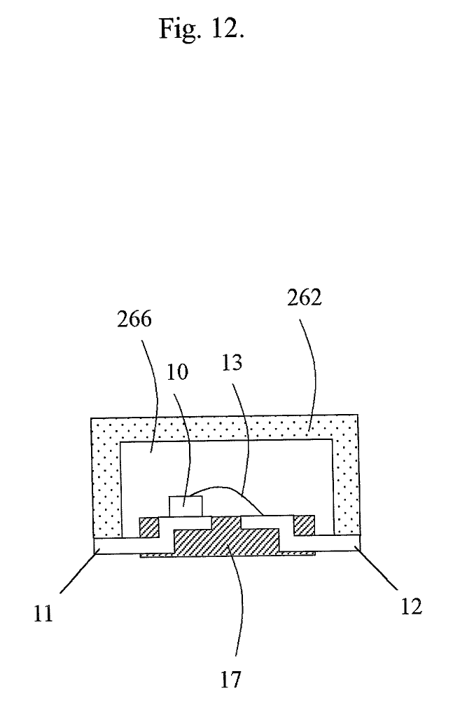

FIG. 12 shows a tenth embodiment of the present invention. The structure is similar to that in FIG. 11 except that the leads 11 and 12 are zigzag. The zigzag bend increases the area imbedded in the glue 17, thereby strengthening the leads 11 and 12.

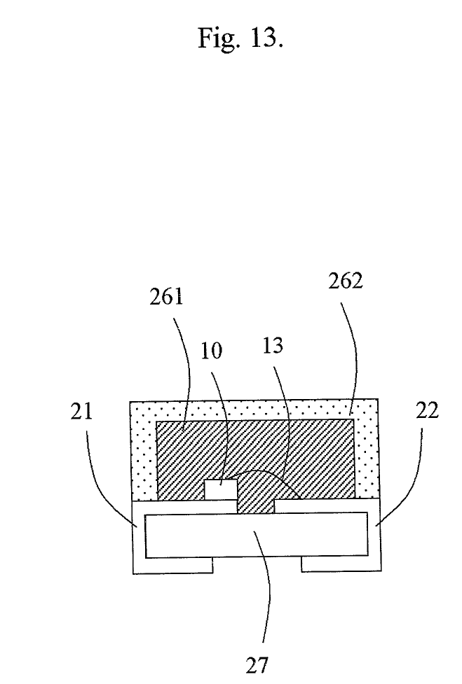

FIG. 13 shows an eleventh embodiment of the present invention. The structure is similar to that in FIG. 7 except that the width of the fluorescent cover 262 is extended to be equal to the length of the folded leads 21 and 22 around the insulating substrate 27. The lengthened fluorescent cover 262, together with the glue 261 makes the folded more rigid.

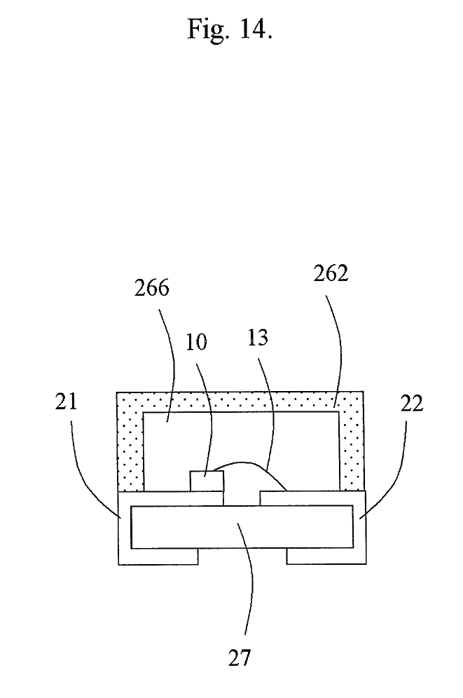

FIG. 14 shows a twelfth embodiment of the present invention. The structure is similar to that in FIG. 8 except that the fluorescent cover 262 is extended to a width equal to the length of the leads 21 and 22. The extended fluorescent cover 262 makes the leads 21 and 22 more rigid.

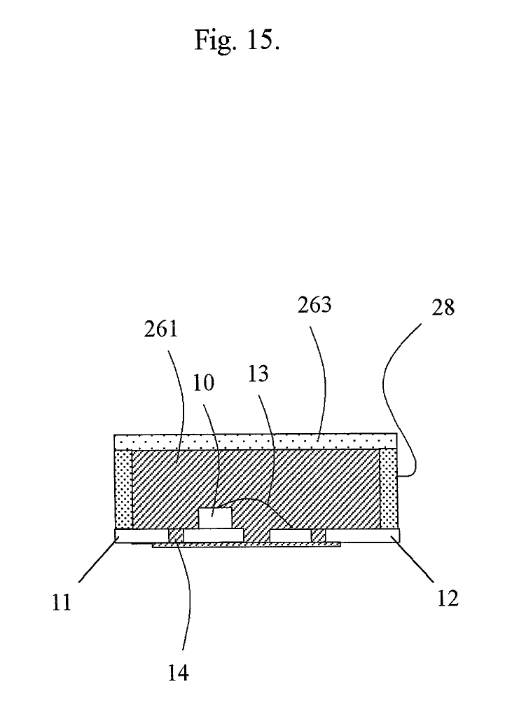

FIG. 15 shows that thirteenth embodiment of the present invention. The structure is similar to that in FIG. 9 except that the fluorescent 263, the glue 261 and the side-wall 28 are extended to a width equal to the length of the leads 11 and 12. The extended glue 261 and the side-wall 28 makes the leads 11, 12 more rigid.

While the preferred embodiment of the invention has been described, it will be apparent to those skilled in the art that various modifications may be made in the embodiments without departing from the spirit of the present invention. Such modifications are all within the scope of this invention.

1. A package for illuminating colorless light, comprising:
light emitting diode (LED) selected from the group consisting of a blue LED and an ultra-violet (UV) LED; and
a fluorescent cover for said LED.

2. The package as described in claim 1, further comprising:
a first metal lead on which the bottom electrode of said LED is mounted and which forms a bottom contact for surface mounting of the package; and
a second metal lead to which the top electrode of said LED is wire-bonded.

3. The package as described in claim 2, further comprising:
two conduits selected from the group consisting of through-holes and edge-recesses, each in said first metal lead and said second metal lead, and
a glue for filling the space between said LED and said fluorescent cover, for filling said through holes, and for spreading along the bottoms of said first metal lead and said second metal lead to bridge said first metal lead and said second metal lead.

4. The package as described in claim 3, wherein said fluorescent cover covers only the top surface of said first glue.

5. The package as described in claim 1, wherein:
the space between said LED and said fluorescent cover is filled with air,
two conduits selected from the group consisting of through-holes and edge-recesses, each in said first metal lead and said second metal lead, and
a glue for filling said through holes and for spreading along the bottoms of said first metal lead and said second metal lead to bridge said first metal lead and said second metal lead together.

6. The package as described in claim 5, wherein said first metal lead and said second metal lead are zigzag in shape and imbedded in a glue for holding said first metal lead and said second lead together.

7. The package as described in claim 2, wherein said first metal lead and said second metal lead are folded around an insulating substrate for holding said first metal lead and said second metal lead together.

8. The package as described in claim 7, wherein the space between the LED and the fluorescent cover is filled with glue.

9. The package as described in claim 7, wherein the space between the LED and the fluorescent cover is filled with air.

10. The package as described in claim 4, wherein an opaque side-wall surrounds said glue.

11. The package as described in claim 2, wherein the width of said fluorescent cover is extended to be the same as the length of said first metal lead and said second metal lead.

12. The package as described in claim 3, wherein the width of the glue and the fluorescent cover is extended to be the same as the length of said first metal lead and of second metal lead.

13. The package as described in claim 5, wherein the width of the fluorescent cover is extended to be the same as the length of said first metal lead and said second metal lead.

14. The package as described in claim 6, wherein the width of the fluorescent cover is extended to be the same as the length of the first metal lead and said second metal lead.

15. The package as described in claim 8, wherein the width of the fluorescent cover is extended to be the same as the length of the first metal lead and said second metal lead.

16. The package as described in claim 9, wherein the width of the fluorescent cover is extended to be the same as the length of the first metal lead and said second metal lead.

17. The package as described in claim 10, wherein the width of the fluorescent cover is extended to be the same as the length of the first metal lead and the second metal lead.
